(19) United States
(12) Patent Application Publication
(10) Pub. No.: US 2009/0181226 A1
(43) Pub. Date: Jul. 16, 2009

(54) METHOD FOR MANUFACTURING METAL LINE EMBEDDED IN SUBSTRATE AND METHOD FOR MANUFACTURING DISPLAY PANEL HAVING THE EMBEDDED METAL LINE

(75) Inventors: Hong-Long Ning, Suwon-si (KR); Chang-Oh Jeong, Suwon-si (KR); Pil-Sang Yun, Seoul (KR); Byeong-Beom Kim, Suwon-si (KR); Je-Hun Lee, Seoul (KR); Do-Hyun Kim, Seoul (KR)

Correspondence Address: Haynes and Boone, LLP;IP Section, 2323 Victory Avenue, SUITE 700, Dallas, TX, 75219, US

(73) Assignee: Samsung Electronics Co., Ltd.

(21) Appl. No.: 12/354,484

(22) Filed: Jan. 15, 2009

(30) Foreign Application Priority Data
Jan. 15, 2008 (KR) 10-2008-0004405

(51) Int. Cl. B32B 7/00; H01L 21/44; H01L 21/02

(52) U.S. Cl. 428/209; 438/660; 438/38; 257/E21.476

(57) ABSTRACT

A method for manufacturing a metal line embedded in a substrate includes forming a trench in the substrate, bringing a stenciling plate having a through hole corresponding to the trench into contact with the substrate with the through hole being aligned to and exposing the trench, applying a fluidic and solidifiable metallic coating material through the through hole and into the trench, separating the stenciling plate from the substrate and solidifying the metallic coating material in the trench.

### CROSS-REFERENCE TO RELATED APPLICATION

This application claims priority to Korean Patent Application No. 10-2008-0004405 filed on Jan. 15, 2008, and all the benefits accruing therefrom under 35 U.S.C. §119, and incorporates by reference the disclosure thereof in its entirety.

### BACKGROUND

1. Field

The present disclosure of invention relates to a method for mass production manufacture of metal lines and more particularly, to a method for manufacturing of embedded metal lines in a substrate of a display panel.

2. Technology

Generally, flat panel display devices display an image by selectively applying electrical signals to a matrix of circuit elements provided on a light-transmissive insulation substrate. Often, it is desirable to form a plurality of metal lines on a light-transmissive insulation substrate so as to apply the electrical signals to the circuit elements.

For instance, a thin film transistor-liquid crystal display (TFT-LCD), which is one type of flat panel display device, includes an array of TFTs (thin film transistors) coupled to drive corresponding liquid crystal capacitors as the array of circuit elements that are to be driven by way of metal lines. The array of metal lines typically includes a first plurality of gate metal lines extending in parallel in a first direction for applying gate turn-on voltage signals to gate terminal of TFTs in respective image lines. The array of metal lines typically further includes a second plurality of data metal lines extending in parallel in a second direction for applying data gradation voltage signals to source terminals of TFTs in respective image columns. Typically these metal lines extend from one end of a display panel (i.e., a light-transmissive substrate such as glass or clear plastic) to the other end opposite to the one end. As the display panel (i.e., light-transmissive substrate) increases in size, the metal lines increase in length, with this often leading to a corresponding increase in end-to-end line resistance of each metal line. There have been several attempts in the art to reduce line resistance of such metal lines, for instance by increasing the cross sectional area of such metal lines. To increase the cross sectional area of such metal lines, a height of each metal line is mainly increased because it is difficult to increase width while maintaining a small line-to-line pitch such as is necessary for high definition images and large aperture ratios. However, increasing of metal line height is also difficult due aspect ratio problems.

While increased height of the metal lines can advantageously reduce the end-to-end line resistance, depending on how the increased height is achieved, it can disadvantageously cause insulation on the sidewalls of each metal line to become unsustainably thin and this can cause the high aspect ratio thin film insulation or the the metal line to collapse. Accordingly, to avoid such phenomena, there has been introduced a technology of manufacturing an embedded metal line formed inside the light-transmissive substrate.

However, conventional methods for manufacturing of such embedded metal lines are complicated. In the conventional manufacturing method, a separate photolithography process, masking process and sputtering process for blanket depositing the metal on the entire masked area, followed by mask removal are performed. Specifically, a photoresist (PR) mask pattern is formed on the light-transmissive substrate through a photolithography process to expose a region of the light-transmissive substrate in which each metal line will be embedded. Thereafter, the exposed region of the light-transmissive substrate is etched through a plasma etching process to thereby form a trench, and then the trench is filled with a metallic thin film using the blanket metal sputtering process. Afterwards, the photoresist mask pattern and excess metallic thin film that is blanket formed on top of the photoresist mask pattern are removed through a lift-off process, thus leaving behind an embedded metal line.

Additionally, since in the conventional method for manufacturing embedded metal lines, a complex and expensive photolithography process is consistently used for each patterning step, this causes the overall manufacturing process to be complicated and manufacturing cost to be increased. Moreover, because the metallic thin film, of which a thickness is similar to the trench depth, is blanket formed to at least that thickness on the photoresist (PR) mask pattern through the metal sputtering process and then removed through the lift-off process, excess metallic material is undesirably consumed and then thrown away with the lifted off, non-reusable PR mask in the manufacture of each individual panel. Further, if the trench is made to be deeper and deeper in order to reduce the total line resistance of each of the metal lines, the metallic thin film left on the photoresist mask pattern becomes thicker so that it is difficult to cleanly remove the metallic thin film and the underlying PR mask with the lift-off process.

### SUMMARY

The present disclosure of invention provide a plurality of methods for use in the mass production manufacturing of embedded metal lines, which methods can simplify the manufacturing process and reduce its costs by forming the embedded metal lines with use, for example; of a low cost printing process in place of photolithography and one-time-only usable PR masks. The methods may further reduce manufacturing costs by minimizing an unnecessary consumption and discard of blanket deposited metallic material used for forming the metal lines.

In accordance with a first embodiment, a method for manufacturing one or more embedded metal lines includes: forming a trench in a light-transmissive substrate; bringing a mask plate into close contact with the light-transmissive substrate, the mask plate having a through hole exposing the trench; applying a fluidic metallic coating material through the through hole of the mask plate and into the trench; and heating the fluidic metallic coating material while in the trench so as to solidify the material and thereby form a solidified metal line.

The applying of the metallic coating material may include: positioning the metallic coating material on the mask plate; and introducing the metallic coating material through the through hole and into the trench by using a squeegee like tool to advance the fluidic metallic coating material across the-area of the mask plate and urge part of the advanced metallic coating material into the trench.

The metallic coating material may be formed of a fluidic material, and may include metal powder particles consisting of one or more of copper (Cu), aluminum (Al), neodymium (Nd), silver (Ag), chromium (Cr), titanium (Ti), tantalum (Ta), cobalt (Co), molybdenum (Mo) and/or various combinations thereof. Herein, the fluidic material may have one of a paste, glue and gel form or it may be a dry powder that is temporarily caused to not easily flow by adding a liquid to it much in the way as beach sand may be molded into a less fluidic form by adding water to a bucket full of dry sand. The metal powder particles of the metallic coating material are sufficiently fine so that each can be easily dropped into the corresponding to-be-filled trench. On the other hand, a substantial portion of the metal powder particles of the metallic coating material are sufficiently large in individual size and concentrated (in terms of particles per unit volume) so that they tend to contact one another after being dropped or otherwise introduced into the trench and such that they form an electrically continuous conductor (which could have small voids therein) after being fused together by sintering heat or other fusing means (e.g., by laser).

The forming of the trench may include: forming an ink mask pattern on the light-transmissive substrate through a printing process, the ink mask pattern exposing a region of the light-transmissive substrate where a metal line is to be formed; removing the exposed region of the light-transmissive substrate; and removing the ink mask pattern.

The forming of the trench may include: forming an insulation layer on the light-transmissive substrate; and removing a portion of the insulation layer corresponding to a region where a metal line is to be formed.

The trench may have a depth ranging from approximately 3,000 Å to approximately 10 μm, and the mask plate may have a thickness ranging from approximately 10% to approximately 100% of the depth of the trench. The height to width aspect ratio of each trench may be greater than 1:1, and possibly greater than 2:1 or more.

The method may further include: removing the mask plate before the firing of the metallic coating material; and planarizing a surface of the light-transmissive substrate through a planarization process after the fusing of the metallic coating material into a solidified continuum of fused together conductive particles.

In accordance with a second embodiment, a method for manufacturing a metal line includes: forming a trench in a light-transmissive substrate; applying a metallic coating material to fill the trench; heating the metallic coating material to thereby solidify it; and planarizing a surface of the light-transmissive substrate through a planarization process.

The filling of the trench may include: positioning the metallic coating material on the light-transmissive substrate; and introducing the metallic coating material into the trench using a squeegee like tool.

The metallic coating material may be formed of a fluidic material having one of paste, glue and gel states, and may include fusible powder particles composed of one of copper (Cu), aluminum (Al), neodymium (Nd), silver (Ag), chromium (Cr), titanium (Ti), tantalum (Ta), cobalt (Co), molybdenum (Mo) and/or various combinations thereof (e.g., alloys or multi-layered particles).

The forming of the trench may include: forming an ink mask pattern on the light-transmissive substrate through a printing process, the ink mask pattern exposing a region of the light-transmissive substrate where a metal line is to be formed; removing the exposed region of the light-transmissive substrate; and removing the ink mask pattern.

The forming of the trench may include: forming an insulation layer on the light-transmissive substrate; and removing a portion of the insulation layer corresponding to a region where a metal line is to be formed.

In accordance with yet another embodiment, a method for manufacturing a display panel includes: forming a plurality of trenches in a substrate; applying a metallic coating material to fill the plurality of trenches; heating the metallic coating material filled into the plurality of trenches so to thereby solidify the material and thus form a gate line with a plurality of gate electrodes integrally branching from the gate line; forming a gate dielectric layer on an entire surface of the substrate; forming an active layer, source and drain electrodes, and a data line, on the gate dielectric layer, with the data line being connected to the source electrode; forming a passivation layer on a resultant structure, the passivation layer exposing a portion of the drain electrode; and forming a pixel electrode on the passivation layer, with the pixel electrode being connected to the exposed portion of the drain electrode.

The method may further include planarizing a surface of the substrate through a planarization process after the forming of the gate line and the gate electrodes.

The filling of the trench may include: bringing a mask plate into close contact with the substrate, the mask plate having a through hole exposing the trench; positioning a fluidic metallic coating material on the mask plate; introducing the metallic coating material into the through hole and the trench by using a squeegee or a squeegee like tool; and removing the mask plate after the trench has been filled.

The metallic coating material may be formed of a fluid material having one of paste, glue and gel like states, and may include one of copper (Cu), aluminum (Al), neodymium (Nd), silver (Ag), chromium (Cr), titanium (Ti), tantalum (Ta), cobalt (Co), molybdenum (Mo) and a combination thereof.

### BRIEF DESCRIPTION OF THE DRAWINGS

Exemplary embodiments can be understood in more detail from the following description taken in conjunction with the accompanying drawings, in which:

FIGS. 1A through 6A are perspective views illustrating a method for manufacturing a metal line in accordance with a first exemplary embodiment;

FIGS. 1B through 6B are sectional views illustrating the method for manufacturing the metal line in accordance with the exemplary embodiment of FIGS. 1A through 6A;

FIGS. 7 and 8 are sectional views illustrating an alignment between a substrate and a mask plate in accordance with the exemplary embodiment of FIGS. 1A through 6A;

FIGS. 9 through 13 are sectional views illustrating a method for manufacturing a metal line in accordance with another exemplary embodiment;

FIGS. 14A through 17A are perspective views illustrating a method for manufacturing a metal line in accordance with still another exemplary embodiment;

FIGS. 14B through 17B are sectional views illustrating the method for manufacturing the metal line in accordance with the exemplary embodiment of FIGS. 14A through 17A;

FIGS. 18 through 20 are sectional views illustrating a method for manufacturing a metal line in accordance with yet another exemplary embodiment; and

FIGS. 21 through 24 are sectional views illustrating a method for manufacturing a display panel having an embedded metal line in accordance with an exemplary embodiment.

### DETAILED DESCRIPTION

Hereinafter, specific embodiments will be described in detail with reference to the accompanying drawings. Other embodiments in accordance with the present disclosure may, however, be provided in different forms and the disclosure should not be construed as limited to the exemplary embodiments set forth herein. Rather, these embodiments are provided so that various concepts will be conveyed to those skilled in the art.

In the figures, the dimensions of layers and regions may be exaggerated for clarity of illustration. Like reference numerals generally refer to like elements throughout. It will also be understood that when a layer, a film, a region or a plate is referred to as being ‘on’ another one, it can be directly on the other one, or one or more intervening layers, films, regions or plates may also be present. Further, it will be understood that when a layer, a film, a region or a plate is referred to as being ‘under’ another one, it can be directly under the other one, and one or more intervening layers, films, regions or plates may also be present. In addition, it will also be understood that when a layer, a film, a region or a plate is referred to as being ‘between’ two layers, films, regions or plates, it can be the only layer, film, region or plate between the two layers, films, regions or plates, or one or more intervening layers, films, regions or plates may also be present.

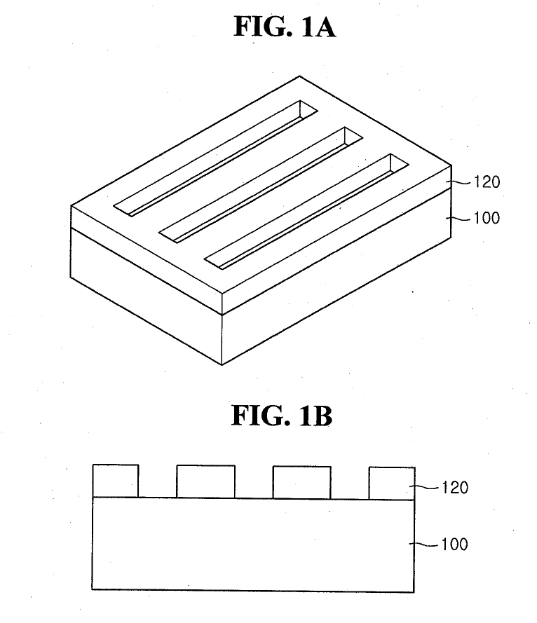

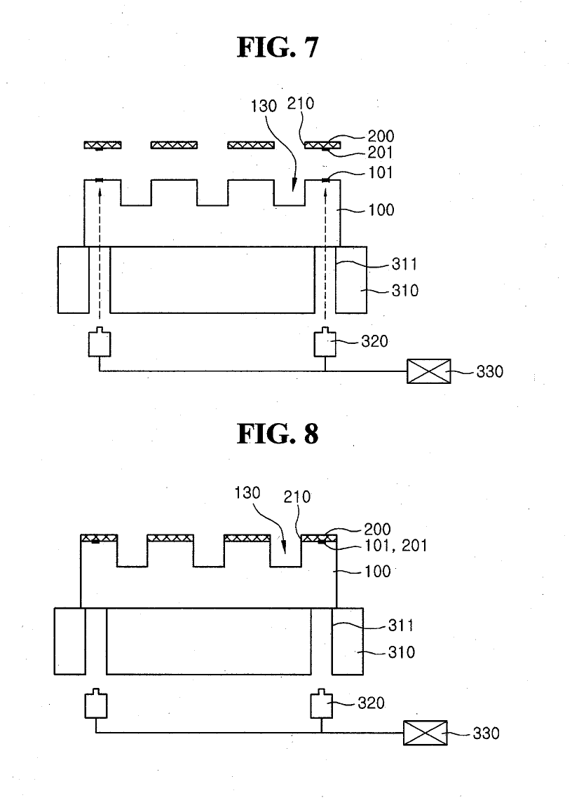

FIGS. 1A through 6A are perspective views illustrating a first method for manufacturing an embedded metal line in accordance with an exemplary embodiment. FIGS. 1B through 6B are sectional views illustrating the method for manufacturing the metal line in accordance with the exemplary embodiment of FIGS. 1A through 6A. FIGS. 7 and 8 are sectional views illustrating an alignment between a substrate and a mask plate in accordance with the exemplary embodiment of FIGS. 1A through 6A.

Referring to FIGS. 1A and 1B, an ink mask pattern 120 is formed on a light-transmissive substrate 100.

Although the light-transmissive substrate 100 includes glass in this exemplary embodiment, the present disclosure is not limited thereto. That is, the substrate 100 may include a substrate having the light transmittance of 80% or higher, for example, a plastic substrate or an acryl substrate. (The plastic should be capable of withstanding a sintering or other solidifying temperature described below.) The substrate 100 is disposed in a printing apparatus (not shown) configured to perform a printing process such a roll on printing process. Subsequently, the ink mask pattern 120 is formed on a surface of the substrate 100. That is, the ink mask pattern 120 may be formed by spraying ink on the surface of the substrate 100 and then drying it, or by printing or rolling on the ink on the substrate 100. As illustrated in FIGS. 1A and 1B, the ink mask pattern 120 exposes predetermined regions of the substrate 100 where trenches will be formed, but shields the other regions of the substrate 100 where the trenches will not to be formed.

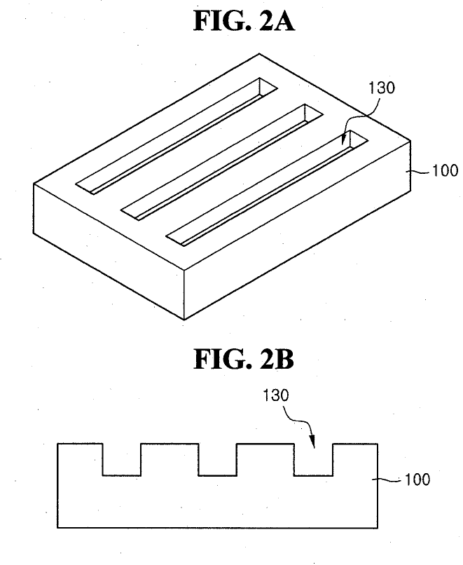

Referring to FIGS. 2A and 2B, the predetermined portion of the substrate 100, which is exposed by the ink mask pattern 120, is selectively removed to a predetermined depth, thereby forming a plurality of trenches 130 in the substrate 100.

In detail, the exposed predetermined portions of the substrate 100 may be removed through a wet etching process using the ink mask pattern 120 as an etch mask. Since a glass substrate is used as the substrate 100 in this exemplary embodiment, an ammonium bifluoride (NH₄HF₂) solution may be used as an etchant for the wet etching process. Of course, sodium ions (Na⁺) or potassium ions (K⁺) may be added into the etchant. However, the usable etchant is not limited to the NH₄HF₂ solution, and thus hydrofluoric acid (HF) solution may be used as the etchant. The acidity (pH) of the etchant may be in the range of approximately 4 to approximately 5. An etch rate of the wet etching process may be in the range of approximately 0.2 μm/min to approximately 0.6 μm/min. If the etch rate is lower than the above-described range, time taken for the wet etching process may become too long. In the contrast, if the etch rate is higher than the above-described range, it is difficult to control the width and/or depth of the wet etching process. The trench 130 formed through the etching process may have a width ranging from approximately 3,000 Å to approximately 10 μm. As described above, a height of the metal line to be formed later may differ depending on the depth of the trench 130. Therefore, if the depth of the trench 130 is smaller than the above-described width range (meaning that the height to thickness aspect ratio is less than 1:1), the line resistance of the metal line will not be increased as desired. On the other hand, if the depth of the trench is much greater than the above-described width range (meaning that the height to thickness aspect ratio is much greater than 1:1), the etching process time may be disadvantageously increased and the high aspect ration trench 130 may fail to be fully filled with a filler material (in other words it may have undesirable voids). Accordingly, an acceptable width of each trench 130, i.e., a linewidth of the corresponding metal line, may be in the range of approximately 2 μm to approximately 30 μm. The trench-forming process, however, is not limited to the aforesaid wet etching process. That is, the trench 130 may be formed by removing the exposed predetermined portions of the substrate 100 through a dry plasma etching process instead of a wet etching process or a combination of both. Moreover, in this exemplary embodiment, the etch mask may employ a photoresist mask pattern formed through a photolithography process instead of the printed-on ink mask pattern 120. Alternatively, the etch mask may employ a photoresist mask pattern which is prepared by printing a photoresist layer. Alternatively, a hard mask layer, which is made of inorganic material, may be used as the etch mask.

After the trenches 130 are formed in the substrate 100 to desired widths and depths, the ink mask pattern 120 is removed.

A fluidic metallic coating material is selectively filled into to-be-filled ones of the trenches through a stencil controlled filling method, which will be described in detail below.

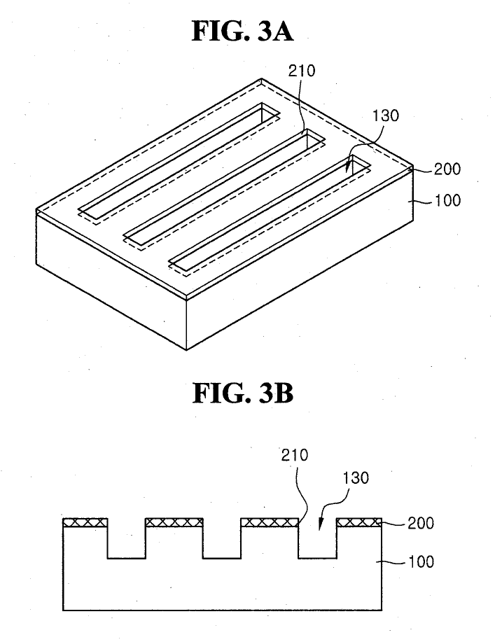

Referring to FIGS. 3A and 3B, a mask plate (stencil) 200 is brought into close contact with the substrate 100 and in alignment with where the to-be-filled trenches 130 are formed.

The mask plate 200 has a plurality of through holes 210. The through holes 210 may be shaped like the to-be-filled trenches 130. As a result, only the to-be-filled trenches 130 are selectively exposed. The remainder of the substrate 100 except for the exposed trenches 130 is shielded by the mask plate (stencil) 200, as shown in FIGS. 3A and 3B.

The mask plate 200 is disposed on the substrate 100 such that the through holes 210 of the mask plate 200 are aligned with the to-be-filled trenches 130 of the substrate 100, where an alignment process will now be described with reference to FIG. 7. Specifically, the substrate 100 with the trenches 130 formed therein is mounted on a supporting stage 310, and the mask plate 200 is then positioned over the substrate 100. Here, optical substrate alignment keys 101 (e.g., optical alignment target patterns) are provided on edges of the top surface of the substrate 100, and mask alignment keys 201 are also provided on edges of the mask plate 200. The stage 310 includes openings 311 exposing a base portion of the substrate 100 corresponding to the substrate alignment key 101. Below the opening 311, one or more cameras 320 (e.g., real time digital imaging cameras or CCD arrays with appropriate focusing and/or magnification means) are positioned to capture images of the substrate alignment keys 101 as the substrate is roughly aligned relative to the stage 310. At one side of the stage 310, an alignment unit 330 is provided to finely align the substrate 100 and the mask plate 200 by the use of the alignment images taken with the alignment cameras 320. Here, since the substrate 100 of this exemplary embodiment employs a light-transmissive glass substrate, the substrate alignment keys 101 on the top surface of the substrate 100 can be observed even though the camera 320 is disposed below the base of the substrate 100 and the mask alignment keys can be brought into the same focal plane and also observed through the light-transmissive glass substrate 100. After that, as illustrated in FIG. 8, the mask plate 200 is disposed on the top surface of the substrate 100. Relative position of the mask 200 and substrate 100 are adjusted while through the cameras 320, it is observed that the substrate alignment keys 101 of the substrate 100 come into fine alignment with the mask alignment keys 201 of the mask plate 200. If the substrate alignment keys 101 are not aligned with the mask alignment keys 201, the mask plate 200 for example is shifted to better align the substrate alignment keys 101 with the mask alignment keys 201. If the substrate alignment keys 101 are aligned to within predefined tolerances with the mask alignment keys 201, the mask plate 200 is temporarily fixed to the substrate 100. Specifically, both ends of the substrate 100 and the mask plate 200 are fixed by the use of one or more fixing members (e.g., clamps) such that they do not become misaligned with each other.

The mask plate 200 fixed to the substrate 100 may be manufactured through the same process as the aforesaid trench-forming process. The mask plate 200 may include a ceramic substrate. Specifically, a low temperature co-fired ceramic (LTCC) sheet may be used as the mask plate 200. The ceramic sheet may be similar in size to the substrate 100. An ink mask pattern is formed on the ceramic sheet, as mentioned above. The shape of the ink mask pattern may have the same shape as the ink mask pattern shown in FIGS. 1A and 1B. Subsequently, the ceramic sheet exposed by the ink mask pattern is removed to thereby manufacture the mask plate 200 with patterns formed. Of course, the present disclosure is not limited to the above-described process, and thus the mask plate 200 may be manufactured through a separate punching process by removing a portion of the ceramic sheet corresponding to the region where the trench is formed.

In this exemplary embodiment, it is possible to easily control the thickness of the mask plate 200 to be uniform because of using the ceramic sheet as the mask plate 200. A fluidic metallic coating material, which will be flowed into and filled into the trenches 130 in a subsequent process, may include a gel material with a predetermined viscosity. The gel material may include a material that can be solidified by heating and/or exposure to UV light or laser beams. In some embodiments, the metallic coating material formed from the hardenable gel may shrink in a height while being sintered or otherwise solidified during a solidifying process. More specifically, the metallic coating material may include metallic powder particles that are initially separated from one another (not fused to one another) due to presence for example of a particle suspending liquid. After the suspension liquid (if any) is selectively removed and/or individual particles are fused to one another, the number of separations or voids within the material may decrease. This loss of volume may cause the hardened metal line to be slightly inwardly concaved relative to the trench 130. On the contrary, in the case where the mask plate 200 is disposed on the top surface of the substrate 100 like this exemplary embodiment, the metallic coating material may be filled in so as to upwardly protrude beyond the top of the trench 130 by virtue of the added thickness provided by the added-on mask plate 200. Hence, although the height of the metallic coating material may be decreased during the solidifying process (e.g., due to volatilization of a suspension liquid and/or due to reduction or elimination of voids), it is possible to prevent the metal line from becoming inwardly concaved below the top of the trench 130 so that planar contact thereto becomes difficult. To this end, the thickness of the mask plate 200 may be varied to correspond with volume loss characteristics of the metallic coating material during solidification whereby the height of the in-trench material is decreased during the solidification process. In one class of embodiments, the metallic coating material used in this exemplary embodiment shrinks in height by approximately 10% to approximately 50% during the solidification process. Accordingly, the mask plate 200 may have a thickness in the range of approximately 10% to approximately 100% of the depth of the trench 130.

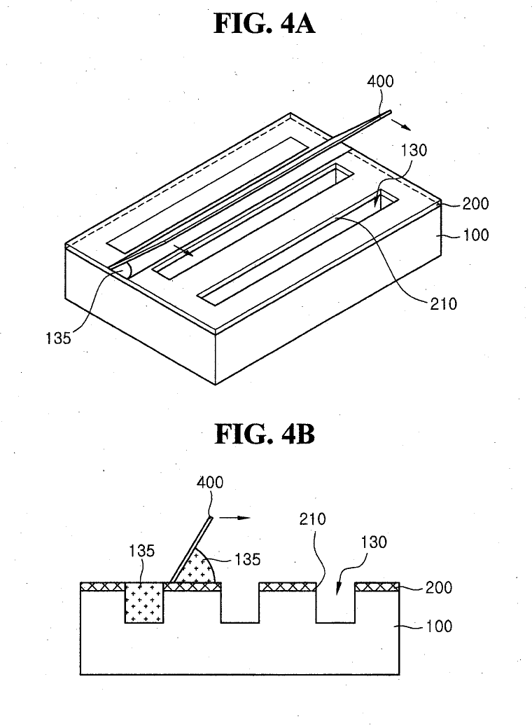

Referring to FIGS. 4A and 4B, the metallic coating material 135 is applied on the mask plate 200 so as to be advanced therealong and to be dropped in through the stencil holes (through holes) so as to fill-in the to-be-filled trenches 130. In this exemplary embodiment, the trench 130 is filled with the metallic coating material 135 through the stencil fill-through process, similar for example, to how ink might pass through a printing stencil in a silk screen printing or screen printing process. That is, the metallic coating material 135 is applied on the mask such that the metallic coating material 135 is advanced across the surface of the mask plate 200 and introduced via the through holes 210 defined in the mask plate 200. The metallic coating material 135 that is introduced into the through holes 210 is filled into the trenches 130 below the through holes 210. In one embodiment, the metallic coating material 135 is deposited as a large elongated clump at one edge of the mask plate 200, as illustrated in FIGS. 4A and 4B and then spread over and pushed into the trenches with use of a spatula-like or squeegee-like tool 400 having a planar edge that is supported by peripheral edge surfaces of the mask plate. Accordingly, the viscous metallic coating material 135 is uniformly advanced across the mask plate 200 and dropped, squeezed or otherwise urged into the openings 210 and trenches 130 using the squeegee-like tool 400 for providing the advancing and urging actions. While the squeegee tool 400 moves at a tilt angle so that one of its edges scrapes the top surface of the mask plate 200, the metallic coating material 135 is shoved forward and urged downwardly by the squeegee tool 400 and is thus introduced into the trenches 130. The squeegee tool 400 does not scrape and thus does not damage the substrate 100 itself. Since the metallic coating material 135 does not adhere to the substrate where the substrate 100 is covered by the mask plate 200, it is possible to prevent excess metallic coating material 135 from remaining on the substrate 100 in places other than in and slightly above the to-be-filled trenches 130.

In one embodiment, the metallic coating material 135 in viscous form includes a liquid having a predetermined viscosity and having fine metal particles distributed therein and suspended thereby. The viscous liquid of this version of the metallic coating material 135 may have the consistency of at least one of a paste, a glue and a gel. Alternatively, the metallic coating material 135 may be a dry fluidic one having the consistency of a fluidic metal powder. The metallic coating material 135 may include powder particles of one or more of copper (Cu), aluminum (Al), neodymium (Nd), silver (Ag), chromium (Cr), titanium (Ti), tantalum (Ta), cobalt (Co), molybdenum (Mo) or alloys or multilayered arrangements of various combinations thereof. The metal powder particles of the metallic coating material are sufficiently fine so that each can be easily dropped into the corresponding to-be-filled trench. On the other hand, a substantial portion of the metal powder particles of the metallic coating material are sufficiently large in individual size and concentrated (in terms of particles per unit volume) so that they tend to contact one another after being dropped or otherwise introduced into the trench and such that they form an electrically continuous conductor (which could have small voids therein) after being fused together by sintering heat or other fusing means (e.g., by laser). The metallic coating material 135 of one embodiment may be prepared in a paste state by mixing an organic solvent or suspension liquid with Cu and/or Cu/Ag powder particles so that the metal powder particles are uniformly distributed in the solvent and can form a good continuous conduction paths for electrical current after the solvent is volatilized and the metal particles are sintered or otherwise fused together.

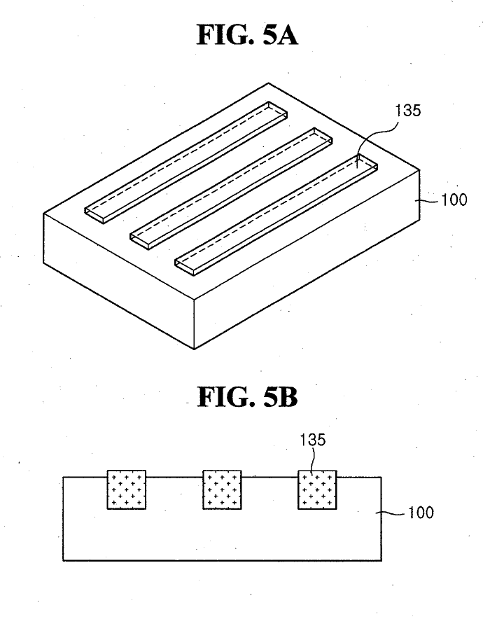

Referring to FIGS. 5A and 5B, after the fluidic metallic coating material 135 has been squeegeed into place and optionally partially hardened, the mask plate 200 is separated from the substrate 100 through a snap-off process.

Specifically, the mask plate 200 in close contact with the substrate 100 is separated vertically away from the substrate 100. For example, if the substrate 100 and the mask plate 200 are fixed to each other by means of the fixing member as described above, the fixing member is removed first and the mask plate 200 is then lifted off orthogonally from the substrate so as to leave the squeegeed in metallic coating material 135 in place. Resultingly, the metallic coating material 135 remains filled into the trenches 130, and the metallic coating material 135 also protrudes higher than the top surface of the substrate 100 by an amount corresponding to the thickness of the lifted away mask plate 200. In order to maintain this desirable protrusion of the metallic coating material 135, the metallic coating material 135 should have a sufficient viscosity (or should be partially prehardened) so as to prevent the protrusion from substantially collapsing (e.g., streaming or flowing down) after the mask plate 200 is lifted away. To this end, in one embodiment, the viscosity of the metallic coating material 135 at the time of plate lift off is in the range of approximately 100,000 CPS to approximately 10,000,000 CPS. The mask plate 200 separated from the substrate 100 may be repeatedly used in a next process with optional wash off of any metallic coating material 135 left on its surface between reuses. Therefore, it is unnecessary to additionally prepare individual mask patterns for every run of the manufacturing process because the same mask plate 200 for filling the metallic coating material 135 into the trenches 130 of one substrate 100 can be reused a plurality of times for other substrates.

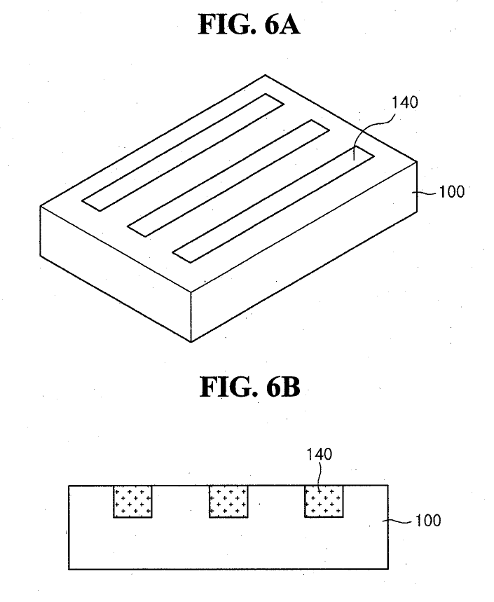

Referring to FIGS. 6A and 6B, the organic solvent (if any) is driven off and the metallic coating material 135 is simultaneously or thereafter sintered or other wise solidified through a heating process to form an electrically continuous metal line 140 having good electrical conductivity.

In detail, the substrate 100 where the metallic coating material 135 is filled into the trenches 130 is loaded into a heating apparatus. Thereafter, the metallic coating material 135 is heated from room temperature to a temperature ranging from approximately 200° C. to approximately 400° C., thereby fusing together the metallic powder particles in the metallic coating material 135. At this point, the metallic coating material 135 shrinks vertically so that its height is decreased because the Cu and/or Cu/Ag powder particles in the metallic coating material 135 are bonded or fused together to thereby form the electrically continuous metal line through the firing process. In one embodiment, any nonconductive additive such as the organic solvent in the metallic coating material 135 may be vaporized and removed. An appropriate removal gas may be flowed through the furnace at appropriate pressures and flow rates for removing the volatilized, nonconductive additives. If the metallic coating material 135 has a paste state, its total height is generally decreased by approximately 10%. However, since the metallic coating material 135 protrudes higher than the top surface of the substrate 100 as described above, it is possible to prevent the metal line 140 from being lowered below the top surface of the substrate 100 even though the metallic coating material 135 shrinks during the solidification process. As illustrated in FIGS. 6A and 6B, the top surface of the substrate 100 can be coplanar with the top surface of the metal line 140. For planarization of the top surface of the substrate 100 and the top surface of the metal line 140, a planarization process may be further performed using, for example, an appropriate chemical mechanical polishing (CMP) process that selectively removes glass faster than metal. In the case where a copper line is formed by coating and firing a copper powder containing paste in the above-described manner, a specific resistance of the post-sintering copper line has been observed in the range of approximately 2.3 μΩ to approximately 3.0 μΩ. The method for manufacturing an embedded metal line is not limited to the previous exemplary embodiment, and thus various methods may be used.

Herebelow, a method for manufacturing a metal line in accordance with another exemplary embodiment will be described. In the below-described exemplary embodiment, duplicate descriptions, which have already been explained for the first embodiment, will be omitted. A mass production manufacturing technology used in the below-described exemplary embodiment is also applicable to the previous embodiment.

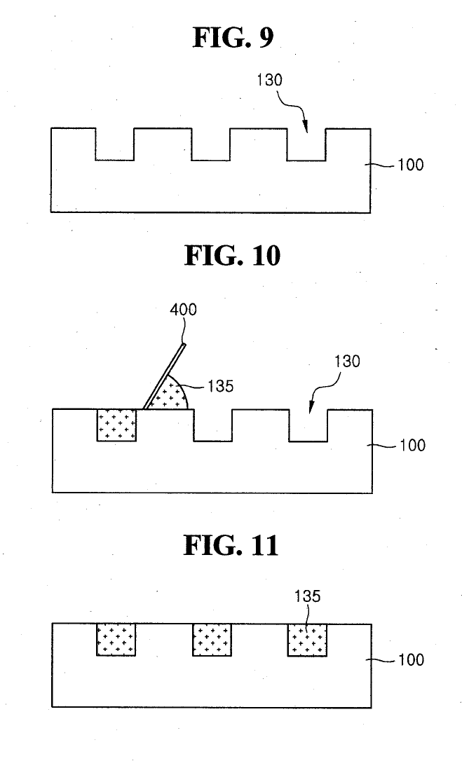

FIGS. 9 through 13 are sectional views illustrating a method for manufacturing embedded metal lines in accordance with another exemplary embodiment;

Referring to FIG. 9, mask-defined portions of a substrate 100 are partially removed to form trenches 130 of prespecified depths and widths. Specifically, the trenches 130 may be formed by removing portions of the substrate 100 where metal lines of corresponding heights and widths will be formed.

Referring to FIGS. 10 and 11, a metallic coating material 135 is filled into the trenches 130 without use of a squeegee masking plate (200).

That is, an elongated clump of the metallic coating material 135 is disposed at one side of the substrate 100. Subsequently, a squeegee 400 or other appropriate spreading tool is brought into close contact with the surface of the substrate 100 and moved so as to redistribute the metallic coating material 135 and force it into the trenches 130. Thus, the metallic coating material 135 is scraped by the squeegee 400 and caused to flow into the trenches 130 of the substrate 100 so that the trenches 130 are filled with the metallic coating material 135. Excess metallic coating material 135 left on the surface of the substrate 100 after all the trenches have been filled may be swept or scraped away by the squeegee 400 or another appropriate tool.

Of course, the method of filling the trench 130 with the metallic coating material 135 is not limited to above-described process, and thus various modifications may be used. For example, the metallic coating material 135 may be filled into the trenches 130 using a spin coating method. Specifically, the metallic coating material 135 is dropped on a central region of the substrate 100 with the trenches 130 formed therein. Thereafter, the substrate 100 is rotated so that the metallic coating material 135 is uniformly spread over the top surface of the substrate 100. Due to a centrifugal force caused by the rotation of the substrate 100, the metallic coating material 135 is spread over the top surface of the substrate 100 from the central region to edge or peripheral regions of the substrate. The metallic coating material 135 is introduced into the trenches 130 by flowing down from the top surface of the substrate 100. As a result, the metallic coating material 135 is filled into the trenches 130. Of course, the present disclosure is not limited to the above-described method. That is, the substrate 100 may be rotated and then the metallic coating material 135 may be dropped onto the central region of the substrate 100. In this case, the metallic coating material 135 may have a viscosity lower than that of the previous examples, that is, may have a viscosity ranging from approximately 1,000 CPS to approximately 20,000 CPS. In virtue of good flowability of the metallic coating material 135, the metallic coating material 135 can be easily introduced into the trench 130. The metallic coating material 135 remaining on the top surface of the substrate 100 may be removed using the squeegee 400. In the spin coating method, the metallic coating material 135 is in more of a liquid state at the beginning and may be given a more viscous texture after it has flowed into the trenches, for example by heating to drive off some of the organic solvent. Alternatively, the metallic coating material 135 may be filled into the trenches using a dipping process.

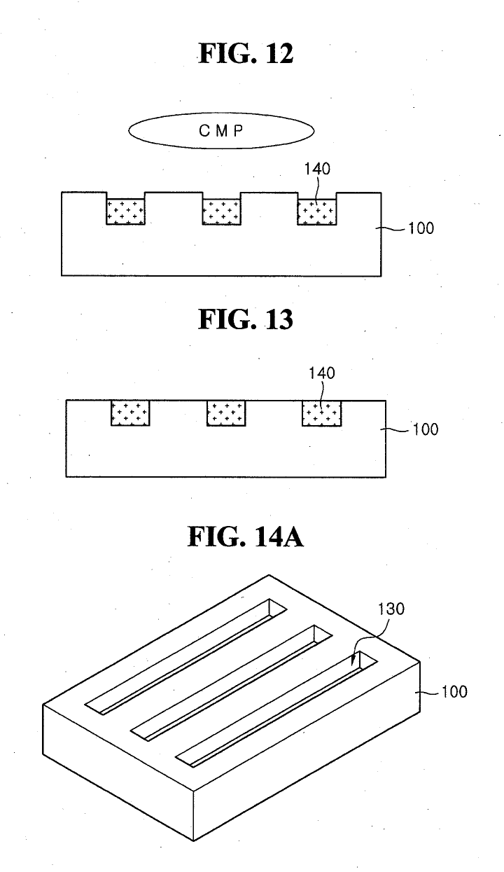

Referring to FIGS. 12 and 13, the metallic coating material 135 in each trench 130 is sintered through firing process to form a continuous metal line 140. In one embodiment, the substrate 100 of which the trenches 130 are filled coated with the metallic coating material 135 is heated from about room temperature to a temperature ranging from approximately 200° C. to approximately 400° C., thereby forming the metal line 140. However, the metal line 140 formed inside the trench 130 through the firing process has a height smaller than the depth of the trench 130 as illustrated in FIG. 12. That is, the top surface of the metal line 140 is lower than the top surface of the substrate 100. To remove stepped portions between the top surfaces of the metal lines 140 and the top surface of the substrate 100, a CMP process (e.g., one that selectively removes glass faster than the sintered line metal) is performed in this exemplary embodiment. Accordingly, a portion of the substrate 100 which is higher than the top surface of the metal lines 140 is removed. As a result, the top surface of the substrate 100 is planarized such that it is coplanar with the top surface of the metal lines 140. Through the CMP process, metallic foreign substances on the substrate 100, which are not completely removed by the squeegee 400, can be clearly removed. Of course, since the stepped portion between the substrate 100 and the metal line 140 may not be so high as to be a problem in some applications, the CMP process may be optionally skipped.

The present disclosure is not limited to the above-described methods. The metallic coating material may be locally injected into each of the trenches. Herebelow, a method for manufacturing a metal line in accordance with still another exemplary embodiment will be described. In the below-described exemplary embodiment, duplicate description, which has been explained in the previous embodiments, will be omitted. A manufacturing technology in the below-described exemplary embodiment is also applicable to the previous embodiments.

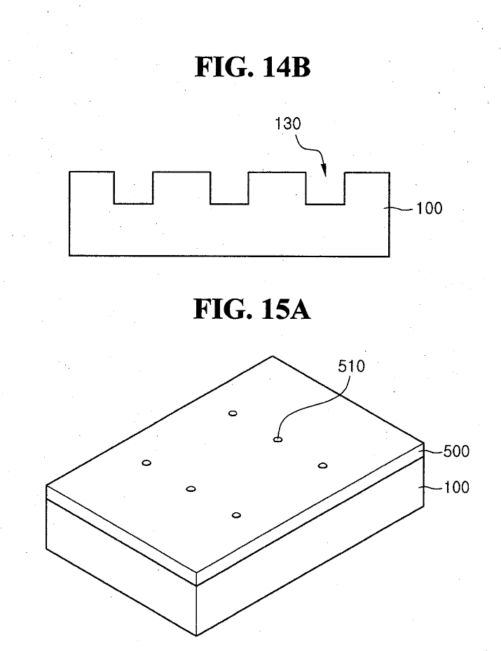

FIGS. 14A through 17A are perspective views illustrating a method for manufacturing a metal line in accordance with still another exemplary embodiment. FIGS. 14B through 17B are sectional views illustrating the method for manufacturing the metal line in accordance with the exemplary embodiment of FIGS. 14A through 17A.

Referring to FIGS. 14A and 14B, prespecified portions of a substrate 100 are selectively removed to form trenches 130 of prespecified widths, depths, apart spacings and/or other configuration parameters (e.g., lengths, degree of parallelness, etc.).

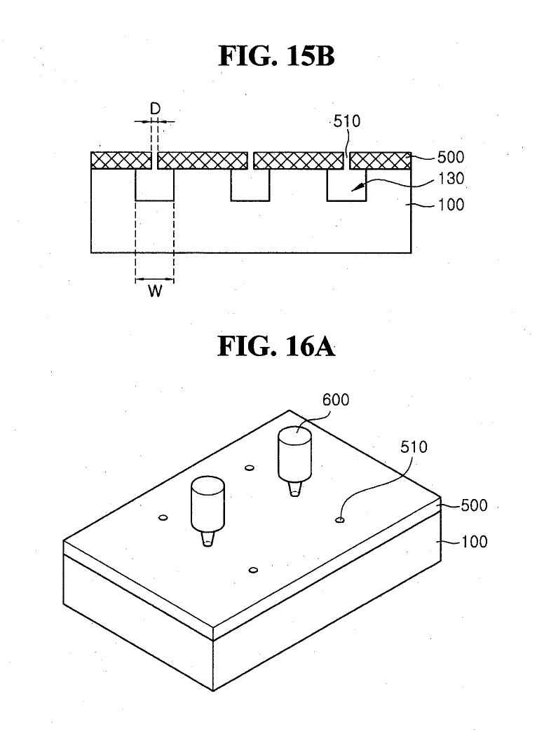

Referring to FIGS. 15A and 15B, an injection mask plate 500 is brought into close contact with the substrate 100. Here, the injection mask plate 500 has a plurality of injection holes 510, with each or each pair corresponding to a respective one of the trenches 130 of the substrate 100. The injection mask plate 500 having the injection holes 150 exposes only one or a few small portions of each trench 130 so that metal powder or a gel thereof may be injected and shields the other regions of the trenches 130 so that the injected material does not substantially escape, as illustrated in FIG. 15. Although this exemplary embodiment of FIG. 15A illustrates that the injection mask plate 500 has two relatively small injection holes 510 for each one trench 130 (one hole for letting air out), the present disclosure of invention is not limited thereto. Therefore, number of the injection holes 510 per trench may be variously modified, i.e., one, two, three, or more. Each injection hole 510 may be formed in a circular shape or alternatively formed in a polygonal shape or an ellipsoidal shape. As illustrated in FIG. 15B, a diameter D of the injection hole 510 may be smaller than a width W of the trench 130. Alternatively, the diameter D of the injection hole 510 may be substantially equal to the width W of the trench 130. The injection mask plate 500 may be similar in size to the substrate 100. The plurality of injection holes 510 may be formed through punching, thus reducing manufacturing cost of the injection mask plate 500.

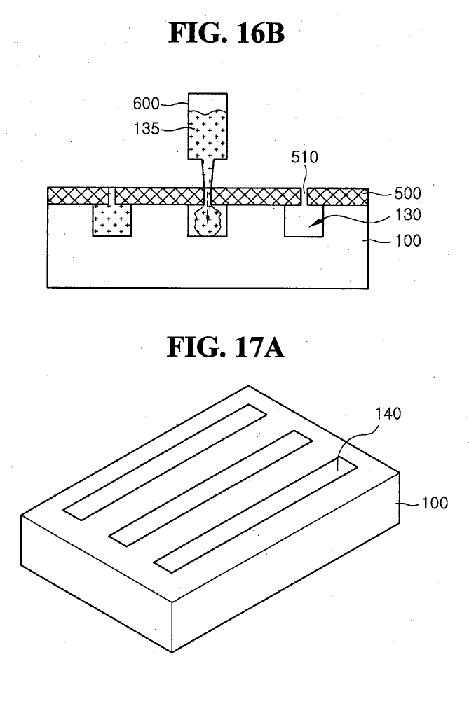

Referring to FIGS. 16A and 16B, a metallic coating material 135 is injected into and fills the respective trenches 130 through corresponding ones of the injection holes 510 of the injection mask plate 500.

In detail, a nozzle of the injector 600 containing the metallic coating material 135 is inserted into the injection hole 510. That is, the nozzle is aligned with the injection hole 510. The metallic coating material 135 is injected through the injector 600. The metallic coating material 135 injected into the trench 130, for example from the center of the trench and uniformly spreads in the trench 130. Typically, air exhaust holes will be positioned at distal ends of each trench. That is, the fluidal metallic coating material 135 injected just below the injection hole 510 spreads out along the inner space of the trench by means of an injection pressure until it spreads and reaches the distal ends of the trench. In this case, because the trench is shielded by the injection mask plate 500, the metallic coating material 135 injected into the inner space of the trench 130 is not leaked out of the trench 130 (except perhaps a small amount from the air exhaust holes, which holes can be smaller than the coating inlet holes). Since the diameter D of the injection hole 150 is smaller than the width W of the trench 130, it IS possible to secure a sufficient process margin. That is, even though the substrate 100 is slightly misaligned with the injection mask plate 500, the metallic coating material 135 can be easily injected into the trench 130 because the injection hole 510 is still placed over the trench 130.

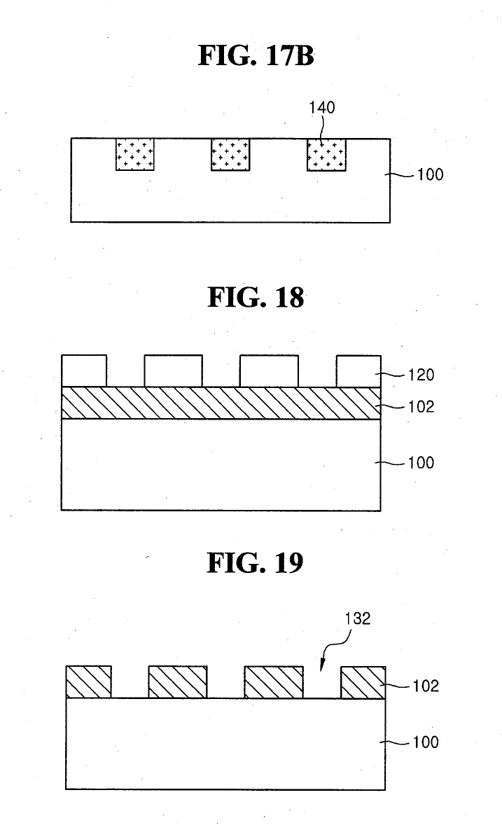

Referring to FIGS. 17A and 17B, the injection mask plate 500 is separated from the substrate 100. Therefore, the trenches 130 can be optionally further filled with the metallic coating material 135 if not so filled by the injection process. Afterwards, the metallic coating material 135 is sintered through firing process to form the metal lines 140 embedded in the trenches 130 of the substrate 100.

The present disclosure is not limited to the above-described methods. The metal lines may be embedded in other types of predetermined insulation layers. Herebelow, a method for manufacturing a metal line in accordance with yet another exemplary embodiment will be described. In the below-described exemplary embodiment, duplicate description, which has been explained in the previous embodiments, will be omitted. A manufacturing technology in the below-described exemplary embodiment is also applicable to the previous embodiments.

FIGS. 18 through 20 are sectional views illustrating a method for manufacturing a metal line in accordance with yet another exemplary embodiment.

Referring to FIG. 18, an insulation layer 102 is formed on a substrate 100, and then an ink mask pattern 120 is formed on the insulation layer 102.

In detail, the insulation layer 102 may include a light-transmissive insulation layer having the light transmittance of 50% or higher. In this exemplary embodiment, the insulation layer 102 may be formed of silicon nitride or silicon oxide. Specifically, a silicon nitride layer is deposited on an entire surface of a glass or other substrate 100 to form the insulation layer 102. Thereafter, the ink mask pattern 120 is formed on the insulation layer 102 to expose a portion of the insulation layer 102 where a metal line will be formed.

Referring to FIG. 19, the exposed portion of the insulation layer 102 is removed to form a trench 132.

The insulation layer 102 is removed through the wet etching process using the ink mask pattern 120 as an etch mask. In the wet etching process, an etchant may include an HF solution. However, the removal of the insulation layer 102 is not limited to the wet etching process, but it may be performed through a dry plasma etching process using a fluorine (F)-based gas. Here, the thickness of the insulation layer 102 becomes the depth of the trench 132. Therefore, the insulation layer 102 may be formed to have a thickness similar to the desired height of the metal lines.

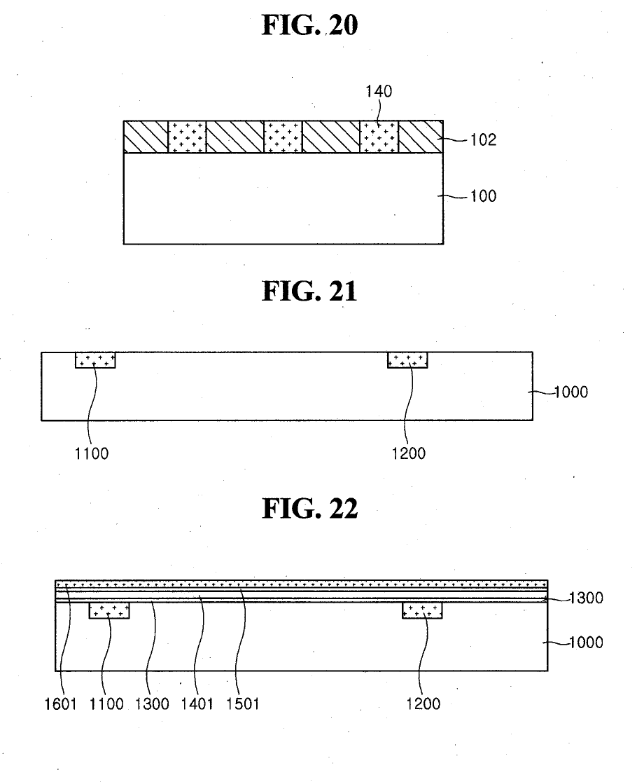

Referring to FIG. 20, a metallic coating material is filled into the trench 132 through a stencil printing method, or an injection, spin coating or paste coating method which does not utilize a mask plate. The metallic coating material is sintered through firing process to thereby form a metal line embedded in the trench 132 of the substrate 100.

Hereinafter, a method for manufacturing a display panel having embedded metal lines of the exemplary embodiments as its gate signal delivering lines will be described.

FIGS. 21 through 24 are sectional views illustrating a method for manufacturing a display panel having embedded metal lines in accordance with an exemplary embodiment.

Referring to FIG. 21, a gate line 1100 and a storage line 1200 are formed in structure parallel trenches of a substrate 1000.

In detail, the trenches are formed in prespecified regions of the substrate 1000 where the gate line 1100 and the storage line 1200 will be formed.

Thereafter, a metallic coating material is filled into the trenches. The metallic coating material may be filled into the trenches using any of the methods described in the exemplary embodiments of FIGS. 1 through 21. Afterwards, the metallic coating material is sintered through firing process to form the gate line 1100 and the storage line 1200. Here, portions of the gate line 1100 repeatedly protrude or branch off horizontally from their main vertical elongations in order to form integral gate electrodes for TFTs that will be formed thereat.

Referring to FIG. 22, a gate dielectric layer 1300, a thin film 1401 for active layer, a thin film 1501 for ohmic layer and a conductive layer 1601 are sequentially formed on an entire surface of the substrate 1000 with the gate line 1100 and the storage line 1200 embedded.

The gate dielectric layer 1300 may be formed of an inorganic insulation material containing silicon oxide and/or silicon nitride. The thin film 1401 for active layer includes am amorphous silicon layer, and the thin film 1501 for ohmic layer includes a silicide layer or an amorphous silicon layer heavily doped with n-type impurities. The conductive layer 1601 includes at least one of Al, Nd, Ag, Cr, Ti, Ta and Mo, or a combination thereof. The layers described herein may be formed using a deposition method such as plasma enhanced chemical vapor deposition (PECVD) and a sputtering.

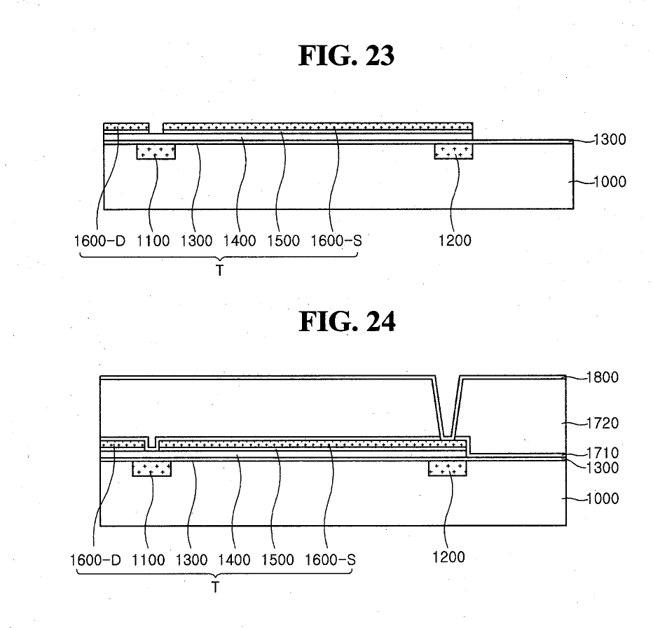

Referring to FIG. 23, the conductive layer 1601, the thin film 1501 for ohmic layer and the thin film 1401 for active layer are partially removed to thereby form an active layer 1400, an ohmic contact layer 1500, a source electrode 1600-S and a drain electrode 1600-D. The gate dielectric layer 1300 and the active layer 1400 are disposed on the gate electrode protruding from the gate line 1100. The source and drain electrodes 1600-S and 1600-D are positioned over the active layer 1400 on the gate electrode. Here, the ohmic contact layer 1500 is provided between the source and drain electrodes 1600-S and 1600-D and the active layer 1400. Therefore, a thin film transistor (TFT) T is completed, which is configured to be operative with the gate electrode, the source electrode 1600-S and the drain electrode-D. A data line connected to the source electrode 1600-S may be formed at the same time.

Referring to FIG. 24, a first passivation layer 1710 and a second passivation layer 1720 are sequentially formed on the substrate 1000 where the TFT (T) is formed. The first passivation layer 1710 may include an inorganic insulation layer containing silicon oxide or silicon nitride. The second passivation layer 1720 includes an organic passivation layer. Subsequently, the first and second passivation layers 1710 and 1720 are partially removed to form a contact hole exposing a portion of the drain electrode 1600-D. Afterwards, a pixel electrode 1800 connected to the drain electrode 1600-D through the contact hole is formed on the second passivation layer 1720. Consequently, an array substrate of a display panel is manufactured.

Although not shown, a common electrode substrate is manufactured, in which a light-shielding pattern (black matrix) and a color filter are formed on a separate substrate and then a common electrode is provided thereon. Subsequently, the array substrate and the common electrode substrate are arranged to face each other, and a liquid crystal material is then injected between the two substrates and sealed therein, thereby completing a liquid crystal display panel.

As described above, in accordance with the exemplary embodiments, one or more trenches are formed in a substrate through a printing process and then a metallic coating material in a paste, glue, gel or fluidic powder form is filled into the trench using a printing method, thus manufacturing an embedded metal line.

Furthermore, in accordance with the exemplary embodiments, it is possible to simplify a manufacturing process of a line and reduce manufacturing costs because the metallic coating material is filled into the trench using a low-cost manufacturing process, i.e., a printing method, and the amount of material wasted per panel can be reduced as well.

Moreover, a mask plate, which is used to fill the metallic coating material into the trenches, can be used a plurality of times, making it possible to reduce manufacturing cost of the embedded metal lines.

Although the a method for manufacturing a metal line and a method for manufacturing a display panel having the metal line have been described with reference to the specific embodiments, they are not limited thereto. Therefore, it will be readily understood by those skilled in the art that various modifications and changes can be made thereto without departing from the spirit and scope of the present disclosure of invention.

What is claimed is:

1. A method for manufacturing an embedded metal line, the method comprising:
forming a trench in a light-transmissive substrate;
bringing a mask plate into close contact with the light-transmissive substrate, the mask plate having a through hole defined therein and exposing the trench;
applying a fluidic metallic coating material through the through hole and into the trench; and
heating the fluidic metallic coating material in the trench so as to thereby solidify the material and form an electrically continuous embedded metal line therefrom.

2. The method of claim 1, wherein the applying of the metallic coating material comprises:
positioning the metallic coating material on the mask plate; and
introducing the metallic coating material into the through hole and into the trench using a squeegee like tool.

3. The method of claim 1, wherein the metallic coating material is formed of a fluidic material, and comprises conductive particles composed of at least one of copper (Cu), aluminum (Al), neodymium (Nd), silver (Ag), chromium (Cr), titanium (Ti), tantalum (Ta), cobalt (Co), and molybdenum (Mo).

4. The method of claim 3, wherein the fluidic material has a consistency of one of a paste, a glue and a gel.

5. The method of claim 1, wherein the forming of the trench comprises:
forming an ink mask pattern on the light-transmissive substrate through a printing process, the ink mask pattern exposing a region of the light-transmissive substrate where a trench is to be formed;
removing the exposed region of the light-transmissive substrate; and
removing the ink mask pattern.

6. The method of claim 1, wherein the forming of the trench comprises:
forming an insulation layer on the light-transmissive substrate; and
removing a portion of the insulation layer corresponding to a region where a trench is to be formed.

7. The method of claim 1, wherein the trench has a depth ranging from approximately 3,000 Å to approximately 10 μm, and the mask plate has a thickness ranging from approximately 10% to approximately 100% of the depth of the trench.

8. The method of claim 1, further comprising:
removing the mask plate before the solidifying of the metallic coating material; and
planarizing a surface of the light-transmissive substrate through a planarization process after the solidifying of the metallic coating material.

9. A method for manufacturing a metal line, the method comprising:
forming a trench in a light-transmissive substrate;
applying a metallic coating material to fill the trench;
heating the metallic coating material so to thereby solidify it; and
planarizing a surface of the light-transmissive substrate through a planarization process.

10. The method of claim 9, wherein the filling of the trench comprises:
positioning the metallic coating material on the light-transmissive substrate; and
introducing the metallic coating material into the trench using a squeegee.

11. The method of claim 9, wherein the metallic coating material is formed of a fluid material having one of paste, glue and gel states, and comprises one of copper (Cu), aluminum (Al), neodymium (Nd), silver (Ag), chromium (Cr), titanium (Ti), tantalum (Ta), cobalt (Co), molybdenum (Mo) or a combination of two or more of said metals.

12. The method of claim 9, wherein the forming of the trench comprises:
forming an ink mask pattern on the light-transmissive substrate through a printing process, the ink mask pattern exposing a region of the light-transmissive substrate where a metal line is to be formed;
removing the exposed region of the light-transmissive substrate; and
removing the ink mask pattern.

13. The method of claim 9, wherein the forming of the trench comprises:
forming an insulation layer on the light-transmissive substrate; and
removing a portion of the insulation layer corresponding to a region where a metal line is to be formed.

14. A method for manufacturing a display panel, the method comprising:
forming a plurality of trenches in a substrate;
applying a fluidic metallic coating material that is solidifiable to fill the plurality of trenches;
solidifying the metallic coating material filled into the plurality of trenches to form an electrically continuous gate line having one or more gate electrodes integrally branching therefrom;
forming a gate dielectric layer on the substrate;
forming an active layer, source and drain electrodes, and a data line, on the gate dielectric layer, the data line being connected to the source electrode;
forming a passivation layer on a resultant structure, the passivation layer exposing a portion of the drain electrode; and
forming a pixel electrode on the passivation layer, the pixel electrode being connected to the exposed portion of the drain electrode.

15. The method of claim 14, further comprising, after the forming of the gate line and the gate electrode, planarizing a surface of the substrate through a planarization process.

16. The method of claim 14, wherein the filling of the trench comprises:
bringing a mask plate into contact with the substrate, the mask plate having a through hole exposing the trench;
positioning the metallic coating material on the mask plate;
introducing the metallic coating material into the through hole and the trench using a squeegee like tool; and
removing the mask plate.

17. The method of claim 14, wherein the metallic coating material is formed of a fluid material having one of paste, glue and gel states, and comprises one of copper (Cu), aluminum (Al), neodymium (Nd), silver (Ag), chromium (Cr), titanium (Ti), tantalum (Ta), cobalt (Co), molybdenum (Mo) and a combination thereof.

18. A light transmissive substrate having a plurality of trenches and a plurality of metal lines embedded in the trenches wherein the embedded metal lines are each formed of metallic powder particles that have been introduced into trenches and fused together within the trenches.
